(19) United States
(12) Patent Application Publication
(10) Pub. No.: US 2026/0012119 A1
(43) Pub. Date: Jan. 8, 2026

(54) VARIABLE SWITCHING FREQUENCY

(71) Applicant: McLaren Applied Limited, Woking (GB)

(72) Inventor: Geoffrey Henfryn Owen, Woking (GB)

(21) Appl. No.: 19/128,498

(22) PCT Filed: Nov. 14, 2023
(86) PCT No.: PCT/GB2023/052983

§ 371 Date: May 8, 2025

(30) Foreign Application Priority Data
Nov. 14, 2022 (GB) 2216972.6

(51) Int. Cl. H02P 27/08; H02P 23/04; H03K 7/08

(52) U.S. Cl. CPC H02P 27/085; H02P 23/04; H03K 7/08

(57) ABSTRACT

A pulse-width modulator (401) comprising a pulse generator (402) configured to generate, at a switching frequency, a pulse-width modulated waveform for synthesising an analog waveform, and a clock unit (403) configured to control the switching frequency and to, while the pulse generator (402) is generating a series of pulses that represents a single respective period of the analogue waveform, change the switching frequency such that at least one pulse in every series is generated at a different switching frequency from other pulses in that series.

The invention relates to apparatus and methods for generating a pulse-width modulated signal.

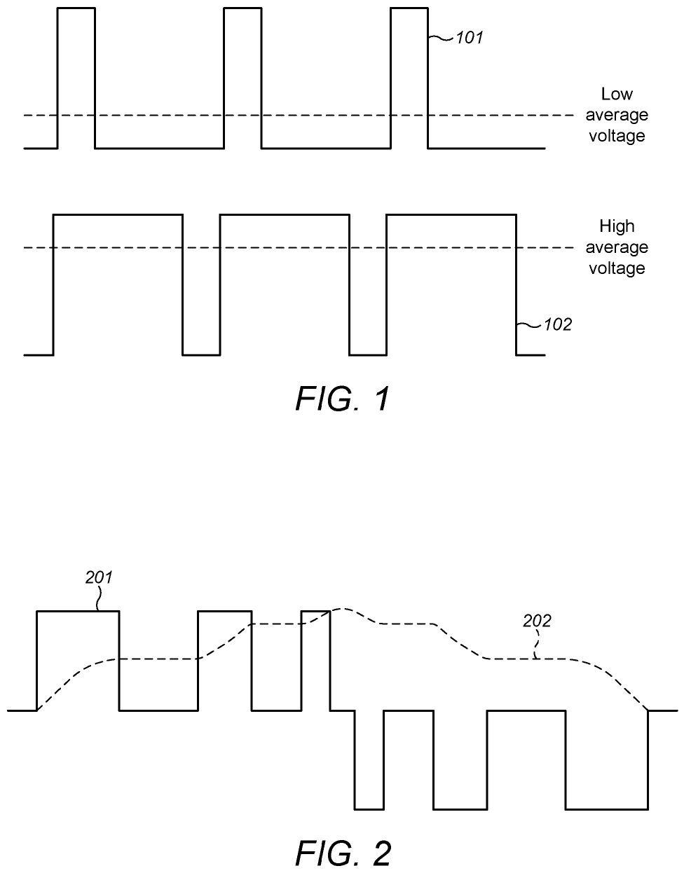

Two examples of pulse-width modulated (PWM) waveforms are shown in FIG. 1 (101, 102). They both comprise a series of rectangular, on-off pulses. The pulses are generated at a switching frequency. The average voltage of the waveform is dependent on the fraction of time that the pulse is on versus off. This is called the duty cycle. Waveforms 101 and 102 have the same switching frequency but different duty cycles, with the result that waveform 102 has a higher average voltage than waveform 101. If the switching frequency is high, the rapid discrete pulses of a pulse-width modulated signal can be considered to synthesise an analogue waveform of lower frequency. An example is shown in FIG. 2, in which PWM signal 201 can be considered as representing the approximate sine wave shown at 202.

PWM waveforms are particularly suited to running inertial loads like motors. The inertia of loads such as these causes them to react slowly to any changes in an input signal, so they are not readily affected by the rapidly-switched discrete pulses of a PWM signal. A PWM signal is digital, but when input into an appropriate load it can effectively appear analogue. An example is shown in FIG. 2 in the sinewave represented by the dotted line 202. The load may be controlled by varying the duty cycle of the PWM signal. This changes the analogue signal that the load perceives. The PWM signal shown in FIG. 2 could, for example, control a motor. The frequency and magnitude of synthesised sinewave 202 can be changed by altering the duty cycle of PWM signal 201. This, in turn, can control the speed of the motor. The result is a mechanism for controlling analogue devices via a digital signal.

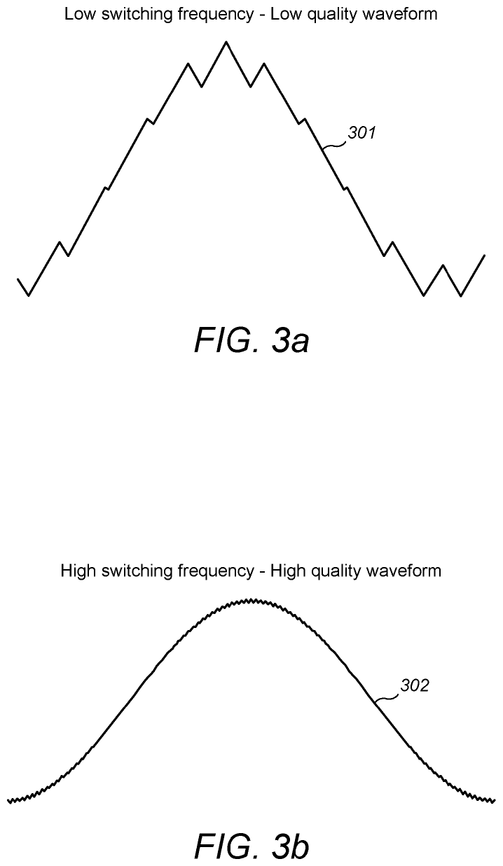

Preferably, the switching frequency of the PWM signal should be high enough that it avoids negatively affecting the load. Preferably, the synthesised analogue waveform is as smooth as possible. This can be explained with reference to the earlier motor example. In motors, a voltage control signal induces a current in the windings. Any deviation of the PWM-synthesised analogue waveform from its ideal equivalent can cause the current to comprise a saw-tooth waveform superimposed over the desired sinewave. This introduces harmonics into the motor which excite the motor coils, generating noise and generating losses. The quality of the motor current waveform produced from the motor controller thus affects the performance of the motor in terms of efficiency and noise. The higher the quality the synthesised waveform (i.e. the “purer” the sinewave) the lower the loss and the higher the efficiency. Historically this has been addressed by using a high fixed switching frequency to generate the PWM signal. In motors, the switching frequency is typically a multiple of 10 or more of the motor fundamental frequency. The difference is illustrated in FIGS. 3a and 3b: the low-quality waveform 301 in FIG. 3a has been induced in a motor coil via a PWM control signal with a low switching frequency whereas the high-quality waveform in FIG. 3b has been induced in a motor coil via a PWM control signal with a high switching frequency.

There is a need for an improved mechanism for generating PWM signals that are intended to synthesise analogue signals.

### SUMMARY OF INVENTION

According to one aspect there is provided a pulse-width modulator comprising a pulse generator configured to generate, at a switching frequency, a pulse-width modulated waveform for synthesising an analogue waveform, and a clock unit configured to control the switching frequency and to, while the pulse generator is generating a series of pulses that represents a single respective period of the analogue waveform, change the switching frequency such that at least one pulse in every series is generated at a different switching frequency from other pulses in that series.

The clock unit may be configured to change the switching frequency so as to control an accuracy with which the pulse-width modulated waveform synthesises the analogue waveform.

The clock unit may be configured to change the switching frequency such that the pulse-width modulated waveform synthesises the analogue waveform within a deviation that is consistent along a period of the ideal analogue waveform.

The clock unit may be configured to control the switching frequency in dependence on a gradient of the analogue waveform.

The clock unit may be configured to, while the pulse generator is generating one or more pulses for synthesising a part of the analogue waveform that has a relatively low gradient, control the switching frequency to be relatively high; and while the pulse generator is generating one or more pulses for synthesising a part of the analogue waveform that has a relatively high gradient, control the switching frequency to be relatively low.

The clock unit may be configured to, while the pulse generator is generating pulses, in each series, that represent a particular section of the period of the analogue waveform, control the switching frequency to be the same so that equivalent pulses across different series are generated at the same switching frequency.

The pulse generator may be configured to generate a pulse-width modulated waveform for synthesising a sinewave.

The pulse generator may be configured to generate a pulse-width modulated waveform for synthesising an analogue voltage waveform.

The pulse generator may be configured to generate a pulse-width modulated waveform for inducing an analogue current waveform in an inductive load.

The pulse generator may be configured to input the pulse-width modulated waveform into a motor.

The pulse generator may be configured to generate the pulse-width modulated waveform for controlling a speed of the motor.

According to a further aspect, there is provided a method comprising generating, at a switching frequency, a pulse-width modulated waveform for synthesising an analogue waveform; and while a series of pulses in the pulse-width modulated waveform that represents a single respective period of the analogue waveform is being generated, change the switching frequency such that at least one pulse in every series is generated at a different switching frequency from other pulses in that series.

The present invention will now be described by way of example with reference to the drawings. In the drawings:

FIG. 1 shows low-average voltage and high-average voltage pulse-width modulated signals;

FIG. 2 shows how a pulse-width modulated signal can approximate a sine wave;

FIGS. 3a and b respectively show low-and high-quality current waveforms induced in a motor coil;

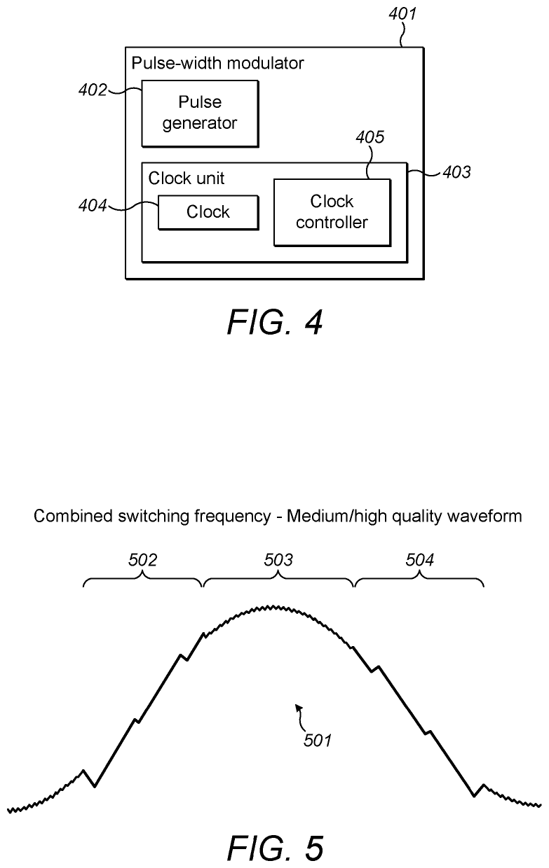

FIG. 4 shows an example of a pulse-width modulator;

FIG. 5 shows an example of a current waveform induced in a motor coil using a variable switching frequency technique;

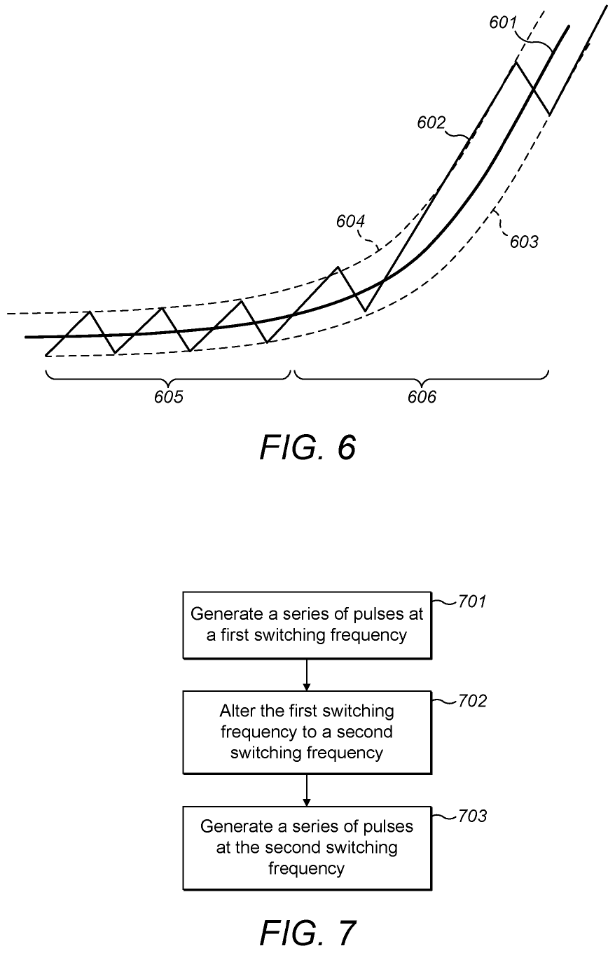

FIG. 6 shows a magnified section of the current waveform shown in FIG. 5;

FIG. 7 shows an example of a method for generating a PWM waveform;

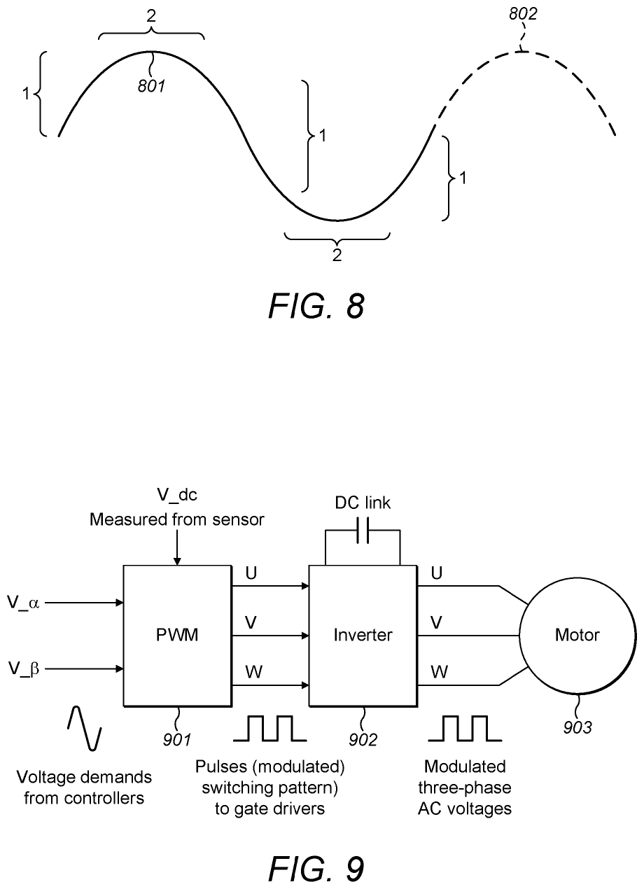

FIG. 8 shows an example of a sinewave with regions that have different levels of susceptibility to ripple; and

FIG. 9 shows an example of a pulse-width modulator used to control a motor.

FIG. 4 shows an example of a pulse-width modulator 401. The pulse-width modulator comprises a pulse generator 402 that is configured to generate a stream of pulses. These pulses form a PWM waveform. The pulse generator is controlled by a clock unit 403 that comprises a clock 404 and a clock controller 405. The clock is input to the pulse generator and determines the switching frequency at which the pulse generator generates pulses. The pulse generator is configured to generate the PWM waveform to synthesise an analogue waveform. The PWM waveform comprises multiple repeated sequences of a particular series of pulses, where each series represents one period of the analogue signal. The clock controller is configured to vary the switching frequency by altering the clock at least once during each series of pulses. In this way at least one pulse in every series is generated at a different switching frequency from other pulses in the same series.

The pulse generator 402 may be configured to generate the pulses to have one of a predetermined set of discrete values. The pulse generator suitably selects the appropriate value for an output pulse at each clocking instant. For example, the pulse generator might comprise a comparator configured to receive a sine wave and a sawtooth wave as inputs (or any other suitable circuitry), and to output either a maximum circuit voltage or a minimum circuit voltage depending on which of its two inputs has the higher value at a particular clocking instant. If the switching frequency increases, the pulse generator selects between those predetermined values more frequently, and vice versa.

The pulse generator is configured to generate the stream of pulses as a digital signal. Typically, the pulses will take one of two values, but could equally take one of three or more different values. The stream of pulses also approximates an analogue signal. An analogue signal is a continuous signal: it may take any value within the range that is possible given the constraints of the circuit implementation.

The PWM waveform is intended to approximate an analogue signal; typically, one that represents a periodic function that repeats at regular intervals. (Examples of periodic functions include sinewaves, square waves, rectangular waves and sawtooth waves etc.) The pulse generator is configured to generate the PWM waveform to comprise a pattern of pulses that reflect an ideal analogue waveform. The desired waveform will typically be a periodic function, and so the pulse generator may be configured to generate the PWM waveform to comprise a series of pulses that repeats at intervals of length P, where P is the period of the ideal analogue waveform. Each series of pulses represents a single period of the analogue waveform. Since the switching frequency of the PWM signal will typically be much higher than the frequency of the desired analogue signal, it will usually be the case that multiple pulses in the PWM signal represent a single period of the analogue signal. This repeating series of pulses is sometimes termed the “representative period” of the PWM waveform in the description that follows. The analogue signal perceived by or induced in a load connected to receive the PWM waveform may have its own respective period. In some implementations that real (as opposed to ideal) signal might not continually repeat the exact same values in the same way as the ideal version (and in accordance with a strict mathematical definition of the term “periodic”). It may nonetheless have a continuous and rhythmic pattern showing lengths of repetition that can be considered a “period”.

The pulse-width modulator 401 is configured to generate the PWM waveform to synthesise an analogue waveform. This “synthesis” can be considered to happen within the pulse-width modulator, with the PWM waveform representing the analogue waveform directly. In other scenarios the waveform that most closely resembles the ideal analogue waveform might exist in a component outside of the pulse-width modulator. For example, in an inertial load to which the pulse-width modulator is connected. In some scenarios the “synthesised” analogue waveform that is of most interest might represent a different variable from the PWM waveform. For example, in motor control, the pulse-width modulator is suitably configured to generate a voltage PWM waveform but the “synthesised” analogue signal that is of most interest to the running of the motor is the current waveform induced in the windings of the motor coils.

In traditional PWM control systems, the switching frequency is kept constant. This tends to lead to the quality of the synthesised analogue signal varying over its period because deviations from the ideal are more perceptible over portions of that signal where the amplitude is relatively stable than in portions where the signal amplitude is changing rapidly (these portions will be termed the “susceptible” parts of the signal). In other words, deviations are more problematic in the relatively flat portions of the synthesised signal than in the relatively steep parts. In many implementations the synthesised analogue signal is required to meet predetermined quality requirements. For example, the synthesised analogue signal might be required to map onto an ideal signal within some predefined limits. Those limits typically apply to the entirety of the synthesised signal. Traditionally the switching frequency is selected to be high enough that the accepted limits will not be breached even in the most susceptible parts of the signal. This is likely to be higher than needed for less susceptible parts of the signal.

Rather than using a fixed switching frequency to generate the PWM waveform, the pulse-width modulator 401 is configured to change the switching frequency at least once during each representative period of the PWM waveform. This may be achieved via clock 404, which can suitably change between at least two different clocking speeds. In one example, the pulses are clocked faster for parts of the PWM waveform that synthesise susceptible sections of the analogue waveform.

An embodiment of the invention will now be described in more detail with reference to a specific implementation in which the pulse generator is configured to generate a PWM waveform that synthesises an analogue voltage signal for controlling a motor. In this implementation it is the analogue current signal that the control signal causes to be induced in the windings of the motor that is the real-world, synthesised analogue signal of interest. It should be understood that this specific implementation is used for the purposes of example only, and the principles described below are equally applicable to other implementations.

FIG. 5 shows an example of a current waveform induced in a motor coil by a PWM voltage waveform. The PWM waveform was generated using a variable switching frequency. The current waveform is shown at 501. The less susceptible parts of the waveform are shown at 502 and 504. These are the times where the current induced in the motor coil is changing rapidly. They correspond to parts of the synthesised analogue voltage waveform that were also changing rapidly. The more susceptible part of the current waveform is shown at 503. This is a time when the current induced in the motor is relatively constant. It corresponds to a part of the analogue voltage waveform that was also relatively constant. The result is a current waveform that displays different levels of quality over its period. In FIG. 5, the current waveform combines medium-and high-quality portions within one period.

FIG. 6 shows a magnified section of the current waveform shown in FIG. 5 at the point of transition between the two switching frequencies. The ideal waveform is shown at 601. The actual current waveform 602 comprises a saw-tooth waveform superimposed over the desired sinewave due to deviations of the PWM-synthesised voltage waveform from its ideal equivalent. The acceptable bounds for the current are shown by dotted lines 603 and 604. The acceptable bounds for a current excited within a motor coil might be in the range 0 to 1 A, 0 to 0.75 A, 0 to 0. , 0 to 0.25 A etc. The acceptable bounds illustrated by dotted lines 603, 604 might be, e.g., ±1 A, ±0.75 A, ±0.5 A, or ±0.25 A of ideal waveform 601.

The ideal waveform 602 is relatively constant in region 605 and then increases rapidly during region 606. The PWM voltage waveform is therefore clocked faster during region 605 than during region 606. The result is higher frequency, lower amplitude current ripple during region 605, when the ideal waveform has a limited capacity to “absorb” any deviations through its own changes in amplitude. In region 606, the rapidly changing amplitude of the ideal waveform essentially accommodates some of the unwanted deviations in the current waveform, with the result that the higher amplitude current ripple caused by using a lower switching frequency is still contained within acceptable boundaries 603, 604. The current waveform therefore maps the idealised waveform within a deviation that is consistent along the period of the analogue waveform, as represented by boundaries 603, 604.

The clock controller 405 of pulse-width modulator 401 is configured to change the switching frequency of pulse generator 402 via clock controller 405 and clock 404 when appropriate. An example of a technique for achieving this is shown in FIG. 7. In step 701 a series of pulses are generated at a first switching frequency. These pulses form a PWM waveform that represents an analogue waveform. The PWM waveform will suitably have a higher frequency than the analogue waveform it is intended to synthesise. In step 702 the switching frequency is changed to a second switching frequency. This change happens during each representative period of the PWM waveform. The pulse generator continues to generate the series of pulses but at the second switching frequency (step 703).

The clock controller 405 may be configured to change the switching frequency once or more per representative period of the PWM signal. The clock controller may be configured to change the switching frequency between two or more different switching frequencies. The clock controller may be configured to use the same switching frequency for pulses in the PWM waveform that represent the same respective sections of periods of the analogue waveform. For example, the clock controller may be configured to start each representative period with the same switching frequency, irrespective of how many switching frequencies it uses during one representative period. The changes that the clock controller makes to the switching frequency across each period—e.g. the particular switching frequencies used, the order in which they are used, the specific points across each period at which the changes are made—are preferably repeated in the same pattern across every series of pulses that forms a representative period of the PWM waveform.

FIG. 8 illustrates an example in which the PWM waveform is intended to synthesise a sinewave. The sinewave, shown generally at 801, represents the ideal analogue signal. It is divided into two susceptibility regions—1 and 2—which the clocking controller is configured to clock differently. Region 1 is clocked in accordance with a first switching frequency (f1) and region 2 is clocked in accordance with a second (f2). The end of one period feeds directly into the start of the next (as shown by dotted line 802). The clocking controller reverts to the first switching frequency at the start of each period. The pattern of switching frequencies (i.e. f1, f2, f1, f2, f1) is repeated for each series of PWM pulses that represents a period of the ideal analogue signal 801.

The clock controller 405 may be configured to control the switching frequency based on any appropriate factor. Examples include:
A gradient of the analogue waveform.
An acceptable boundary within which the synthesised signal is permitted to deviate from the ideal analogue signal.
The specific application, e.g., the specific load that is being driven, the task that the load is performing, the load variable that is being controlled etc.
A required quality of the synthesised signal.
The type of analogue waveform being synthesised.
An optimal power loss by the switching circuit and/or load

In some applications the clock controller may control the switching frequency based on some quality of the analogue signal that the clock controller detects itself, e.g. its gradient or similar. The clock controller could be configured to make such determinations in real-time, while the pulse-width modulator 401 is in use. In other implementations decisions about switching frequency are made in advance and made available to the clock controller, e.g., through a data store, such as a look-up table or similar. For example, appropriate switching frequencies for a motor might be determined through advance experimentation, e.g., by monitoring the current generated in the coils at different switching frequencies to determine how to keep current ripple within acceptable bounds.

The clock controller 405 may be configured to control any aspect of the switching frequency. Examples include:
The exact switching frequencies used
A minimum switching frequency used.
The number of times the switching frequency is changed during a period.
The timings of changing from one switching frequency to another

In some applications there may be additional factors that cause the clock controller 405 to change the switching frequency. One example is when the pulse-width modulator 401 is configured to drive a motor. In this application there is a base switching frequency that is determined by the fundamental frequency of the motor. The higher the fundamental frequency, the higher the base switching frequency (i.e., the base switching frequency is determined by how fast the motor is required to spin). If the speed of the motor is changed then the base switching frequency also changes. In other applications there might be a fundamental quality requirement that sets a base switching frequency, and which may from time-to-time be changed. The periodic changes in switching frequency described above can be superimposed upon a base switching frequency, which may itself change from time-to-time. Changes in a base switching frequency are unlikely to occur at regular, predictable time intervals, nor are they likely to occur in every period of the pulse-width modulated signal.

The pulse-width modulator 401 will now be described in more detail with respect to a particular example in which the pulse-width modulator forms part of a motor drive circuit. This is for the purposes of example only. The principles described herein can be applied to any implementation where pulse-width modulation might usefully be employed. Examples include inductive hobs, LED driver circuits, ultrasonic cleaning, power generation etc.

A schematic diagram of a motor control system is shown in FIG. 9. The system comprises a pulse-width modulator 901, an inverter 902 and a motor 903. The voltage demands calculated by the controllers (not shown) are modulated into pulses by the pulse-width modulator. The varying pulse width of the PWM waveform re-constructs a sinewave voltage waveform output. This waveform drives gate drivers in the inverter, thereby converting DC-link voltage into equivalent three-phase AC voltages that drive the motor.

The frequency and magnitude of the sinewave synthesised by the PWM waveform can be altered to create variable speed drive of the motor. (Other waveform shapes are also used in motor control. Examples include trapezoidal and sinewaves with harmonic injection). The quality of the waveform affects the efficiency and noise generated by the motor, which are of high importance in electric vehicle and other applications. Varying the switching frequency over the period of the sinewave optimises the switching so that a higher switching frequency for lower ripple is only used where needed. This enables a lower switching frequency to be used where the lower ripple is not needed, whilst still keeping the current ripple within upper and lower limits. This results in a spread spectrum of noise and reduces harmonics, audible noise, and reduction in loss within the motor and inverter due to the improved motor current waveform. The achievable reduction in switching frequency is load dependent but could be as high as 50%.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

1. A pulse-width modulator comprising:
a pulse generator configured to generate, at a switching frequency, a pulse-width modulated waveform for synthesising an analogue waveform; and
a clock unit configured to control the switching frequency and to, while the pulse generator is generating a series of pulses that represents a single respective period of the analogue waveform, change the switching frequency such that at least one pulse in every series is generated at a different switching frequency from other pulses in that series;
wherein the clock unit is configured to, while the pulse generator is generating pulses, in each series, that represent a particular section of the period of the analogue waveform, control the switching frequency to be the same so that equivalent pulses across different series are generated at the same switching frequency.

2. A pulse-width modulator as claimed in claim 1, wherein the clock unit is configured to change the switching frequency so as to control an accuracy with which the pulse-width modulated waveform synthesises the analogue waveform.

3. A pulse-width modulator as claimed in claim 1, wherein the clock unit is configured to change the switching frequency such that the pulse-width modulated waveform synthesises the analogue waveform within a deviation that is consistent along a period of the ideal analogue waveform.

4. A pulse-width modulator as claimed in claim 1, wherein the clock unit is configured to control the switching frequency in dependence on a gradient of the analogue waveform.

5. A pulse-width modulator as claimed in claim 1, wherein the clock unit is configured to:
while the pulse generator is generating one or more pulses for synthesising a part of the analogue waveform that has a relatively low gradient, control the switching frequency to be relatively high; and
while the pulse generator is generating one or more pulses for synthesising a part of the analogue waveform that has a relatively high gradient, control the switching frequency to be relatively low.

6. A pulse-width modulator as claimed in claim 1, wherein the pulse generator is configured to generate a pulse-width modulated waveform for synthesising a sinewave.

7. A pulse-width modulator as claimed in claim 1, wherein the pulse generator is configured to generate a pulse-width modulated waveform for synthesising an analogue voltage waveform.

8. A pulse-width modulator as claimed in claim 1, wherein the pulse generator is configured to generate a pulse-width modulated waveform for inducing an analogue current waveform in an inductive load.

9. A pulse-width modulator as claimed in claim 1, wherein the pulse generator is configured to input a pulse-width modulated waveform into a motor.

10. A pulse-width modulator as claimed in claim 1, wherein the pulse generator is configured to generate a pulse-width modulated waveform for controlling a speed of a motor.

11. A method comprising:
generating, at a switching frequency, a pulse-width modulated waveform for synthesising an analogue waveform; and
while a series of pulses in the pulse-width modulated waveform that represents a single respective period of the analogue waveform is being generated, changing the switching frequency, by a clock unit, such that at least one pulse in every series is generated at a different switching frequency from other pulses in that series;
wherein the clock unit is configured to, while the pulse generator is generating pulses, in each series, that represent a particular section of the period of the analogue waveform, control the switching frequency to be the same so that equivalent pulses across different series are generated at the same switching frequency.
